(19) United States
(12) Patent Application Publication
(10) Pub. No.: US 2005/0130438 A1
(43) Pub. Date: Jun. 16, 2005

(54) Method of fabricating a dielectric layer for a semiconductor structure

(75) Inventors: Antonio L.P. Rotondaro, Dallas, TX (US); Luigi Colombo, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 10/736,444

(22) Filed: Dec. 15, 2003

(51) Int. Cl. H01L 21/31; H01L 21/469

(52) U.S. Cl. 438/762; 438/763; 438/789; 438/793

(57) ABSTRACT

Fabricating a semiconductor structure includes establishing a non-stoichiometry associated with a dielectric layer, where the degree of non-stoichiometry corresponds to a nitrogen profile of the dielectric layer. Deposition of the dielectric layer outwardly from a substrate is controlled to substantially yield the established non-stoichiometry of the dielectric layer. Nitrogen is incorporated into the dielectric layer to substantially yield the nitrogen profile without nitridation of the interface.

### TECHNICAL FIELD

This invention relates generally to the field of integrated circuit fabrication and specifically to a method of fabricating a dielectric layer for a semiconductor structure.

### BACKGROUND OF THE DISCLOSURE

Semiconductor devices typically include a dielectric layer. In some devices, the dielectric layer may comprise an oxynitride layer, which may have a larger dielectric constant than that of a silicon dioxide layer. Known techniques for forming an oxynitride layer involve introducing nitrogen into a dielectric layer. These known techniques, however, typically do not effectively or efficiently introduce nitrogen into the dielectric layer. It may be generally desirable to effectively and efficiently introduce nitrogen into the dielectric layer.

### SUMMARY OF THE DISCLOSURE

In accordance with the present invention, disadvantages and problems associated with previous techniques for fabricating a semiconductor structure may be reduced or eliminated.

According to one embodiment of the present invention, fabricating a semiconductor structure includes establishing a non-stoichiometry associated with a dielectric layer, where the degree of non-stoichiometry may correspond to a nitrogen profile of the dielectric layer. Deposition of the dielectric layer outwardly from a substrate is controlled to substantially yield the established non-stoichiometry of the dielectric layer. The dielectric layer typically includes a non-stoichiometric portion. Nitrogen is incorporated into the dielectric layer to substantially yield the nitrogen profile.

Certain embodiments of the invention may provide one or more technical advantages. A technical advantage of one embodiment may include forming a dielectric layer by depositing silicon oxide outwardly from a substrate, which may allow for formation at relatively low temperatures. Another technical advantage of one embodiment may be that the relative concentration of silicon and oxygen of the dielectric layer may be controlled to provide for specific nitridation. This may allow for a desired nitrogen profile for the dielectric layer.

Certain embodiments of the invention may include none, some, or all of the above technical advantages. One or more other technical advantages may be readily apparent to one skilled in the art from the figures, descriptions, and claims included herein.

### BRIEF DESCRIPTION OF THE DRAWINGS

For a more complete understanding of the present invention and its features and advantages, reference is now made to the following description, taken in conjunction with the accompanying drawings, in which:

FIG. 1 illustrates one embodiment of a substrate of a semiconductor structure;

FIG. 2 illustrates one embodiment of a dielectric layer deposited outwardly from the substrate;

FIG. 3 illustrates example timing diagrams for depositing the dielectric layer;

FIG. 4 illustrates one embodiment of nitridation of the dielectric layer; and

FIG. 5 is a flowchart illustrating one embodiment of a method of fabricating a semiconductor structure.

### DETAILED DESCRIPTION OF THE DRAWINGS

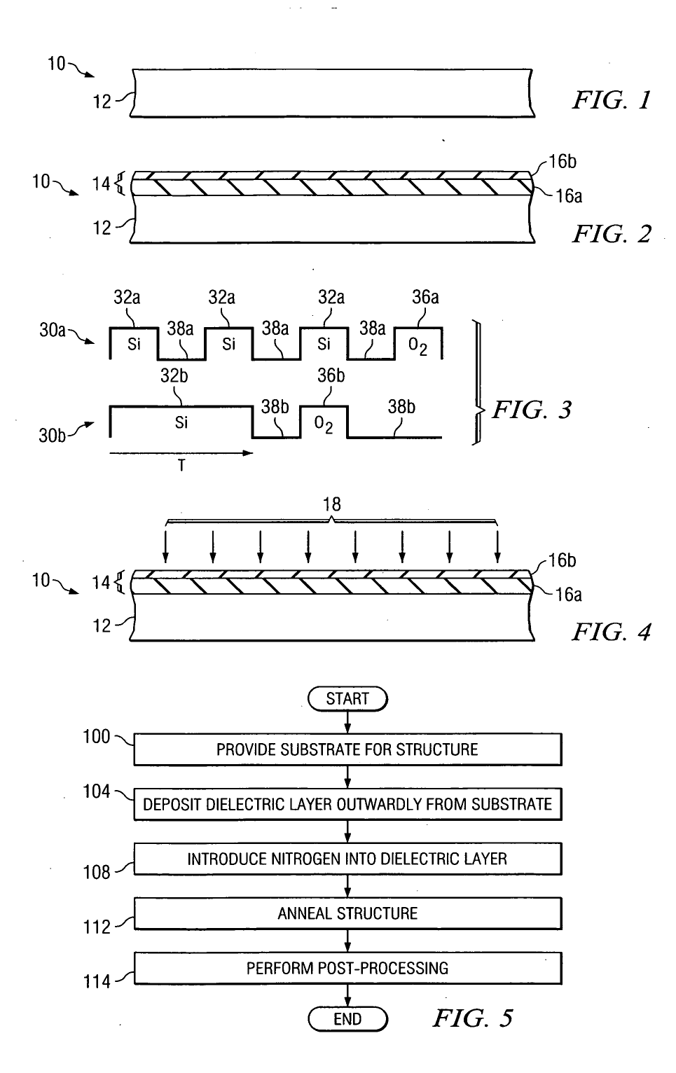

Embodiments of the present invention and its advantages are best understood by referring to FIGS. 1 through 5 of the drawings, like numerals being used for like and corresponding parts of the various drawings.

FIGS. 1, 2, and 4 are a series of schematic cross-sectional diagrams illustrating one embodiment of a method of fabricating a semiconductor structure 10. Semiconductor structure 10 may be formed for various purposes, for example, for use in connection with a transistor of a p-channel metal oxide semiconductor (PMOS) or an n-channel metal oxide semiconductor (NMOS) device.

FIG. 1 illustrates a substrate 12 of semiconductor structure 10. Substrate 12 may provide, for example, a transistor channel for a transistor, and may comprise silicon or any other suitable semiconductive material. Semiconductor structure 10 may be placed in a chamber during formation.

FIG. 2 illustrates a dielectric layer 14 deposited outwardly from substrate 12. Dielectric layer 14 may provide, for example, a transistor gate insulator for a transistor. Dielectric layer 14 comprises dielectric material and may have any suitable thickness such as between one monolayer to 25 Angstroms, for example, 20 Angstroms. Dielectric layer 14 may comprise a non-stoichiometric portion 16a and a stoichiometric portion 16b. The stoichiometry of dielectric layer 14 may refer to the relative proportion of elements of dielectric layer 14. As an example, the composition may refer to the proportion of silicon relative to oxygen.

Stoichiometric portion 16b of dielectric layer 14 may comprise stoichiometric silicon dioxide (SiO₂) material. Stoichiometric portion 16b may be referred to as stoichiometric because the interface trap density Dᵢₜ of SiO₂ is relatively low, typically approximately 10¹⁰/cm2. Non-stoichiometric portion 16a may comprise non-stoichiometric silicon oxide (Si_{z}O_{y}) material, where variables z and y represent the proportion of silicon relative to oxygen and have any suitable values. Non-stoichiometric portion 16a may be referred to as non-stoichiometric if the interface trap density Dᵢₜ of Si_{z}O_{y} is greater than the interface trap density Dᵢₜ of SiO₂.

The interface trap density Dᵢₜ is typically affected by the proportion of silicon relative to oxygen. The interface trap density Dᵢₜ of Si_{z}O_{y} may be greater when Si_{z}O_{y} is silicon-rich as compared to SiO₂, that is, Si_{z}O_{y} has excess silicon relative to oxygen, as compared to SiO₂. According to one embodiment, variables z and y of Si_{z}O_{y} may have values where the ratio of y/z is less than two. These values indicate that on average throughout the Si_{z}O_{y} material, certain molecules having an individual silicon atom have only one bonded oxygen atom rather than two atoms as is the case for the SiO₂ material.

Non-stoichiometric portion 16a may comprise any suitable portion of dielectric layer 14. For example, non-stoichiometric portion 16a may comprise a substantial portion of dielectric layer 14 proximate to substrate 12. Non-stoichiometric portion 16a may comprise at least 45% of the total thickness of dielectric layer 14. For example if dielectric layer 14 has a thickness of 20 Angstroms, non-stoichiometric portion 16a may have a thickness greater than two or three monolayers. As another example, non-stoichiometric portion 16a may be thicker than stoichiometric portion 16b, and may comprise at least 80% of the total thickness of dielectric layer 14. According to one embodiment, stoichiometric portion 16b may be as thin as possible or eliminated altogether.

The stoichiometry of dielectric layer 14 affects the nitridation of dielectric layer 14 that may be performed to form an oxynitride layer. Typically, more nitrogen may be introduced in non-stoichiometric layer 16b than in stoichiometric layer 16a. Accordingly, the stoichiometry may be adjusted to achieve nitridation of dielectric layer 14 for a desired nitrogen profile. A nitrogen profile may refer to the distribution of nitrogen within a material. The stoichiometry may be controlled in any suitable manner. As an example, dielectric layer 14 may be deposited in a controlled manner in order to achieve a specific stoichiometry.

Dielectric layer 14 may be deposited outwardly from substrate 12 according to any suitable process, for example, a chemical vapor deposition (CVD) process or an atomic layer deposition (ALD). According to the chemical vapor deposition process, substrate 12 is exposed to an appropriate precursor such as SiH₄, Si[N (C₂H₅)₂] ₄, Si[N(CH₃)₂]₄, Si(OC₂H₅)₄, Si₂H₆, H₂SiCl₂, SiCl₄, or other suitable precursor and an oxidizer such as O₂, NO₂, NO, O₃, oxygen plasma, or other oxidizer to deposit a silicon dioxide film of the desired stoichiometry outwardly from substrate 12.

According to the atomic layer deposition process, substrate 12 is exposed to a silicon precursor such as SiH₄, Si[N(C₂H₅)₂]₄, Si[N(CH₃)₂]₄, Si(OC₂H₅)₄, Si₂H₆, H₂SiCl₂, SiCl₄, or other suitable precursor and an oxidizer such as O₂, N₂O, NO, H₂O, O₃, oxygen plasma, or other suitable oxidizer in an alternating fashion. For example, substrate 12 with appropriate surface preparation may be exposed to a gas flow comprising a silicon precursor introduced into the chamber during a first pulse, and then a gas flow comprising an oxidizer introduced during a second pulse. A pulse refers to the act of exposing substrate 12 to a gas flow. An oxidizer may comprise, for example, oxygen (O₂), ozone (O₃), other oxidizer, or any combination of the preceding. The silicon carrier may comprise, for example, SiH₄, Si[N(C₂H₅)₂]₄, Si[N(CH₃)₂]₄, Si(OC₂H5)₄, Si₂H₆, H₂SiCl₂, SiCl₄, or other suitable precursor.

The duration of an individual pulse or a sequence of pulses, the gas flow, or both the duration and gas flow may be adjusted to deposit a specific amount of atoms outwardly from the surface. The pressure and flow rate may be adjusted to achieve the appropriate film uniformity deposited outwardly from substrate 12.

The amount of atoms deposited outwardly from substrate 12 by a gas flow may be estimated. A gas flow may deposit a certain concentration of atoms at a specific gas flow rate and pressure that deposits a certain amount of atoms during a unit time. Given the deposited amount per unit time and the duration of a pulse or sequence of pulses, the amount deposited during the pulse or sequence of pulses may be estimated. Accordingly, the amount of oxygen and silicon deposited may be controlled by adjusting the duration, number, or both duration and number of pulses. Example timing diagrams for pulses of silicon and oxygen are described in more detail with reference to FIG. 3.

FIG. 3 illustrates example timing diagrams 30 for pulses of silicon and oxygen. Timing diagram 30a illustrates controlling the proportion of silicon relative to oxygen by adjusting the number of pulses. Timing diagram 30a includes silicon pulses 32a, an oxidizer pulse 36a, and resting time 38a. Silicon pulses 32a represent pulses for depositing silicon, and may have a duration of 0.1 to 60 seconds for a gas flow of 10 sccm to 500 sccm of precursor. Oxidizer pulse 36a represents a pulse for depositing oxygen, and may have a duration of 0.1 to 100 seconds for a gas flow of 0.1 sccm to 10,000 sccm. Resting time 38a represents a time during which there is no pulse.

According to the illustrated embodiment, three silicon pulses 32a and one oxidizer pulse 36a may be used to deposit a specific proportion of silicon relative to oxygen. Any suitable number of silicon pulses 32a, any suitable number of oxidizer pulses 36a, or any sequence of silicon pulses 32a and oxidizer pulses 36a, however, may be used to achieve a desired proportion of silicon relative to oxygen.

Timing diagram 30b illustrates controlling the proportion of silicon relative to oxygen by adjusting the duration of a silicon pulse 32b and an oxidizer pulse 36b. According to the illustrated embodiment, silicon pulse 32b has a longer duration than oxidizer pulse 36b, which may result in a higher proportion of silicon atoms. Silicon pulse 32b may have a duration of five seconds for a gas flow of 100 sccm, and oxidizer pulse 36b may have a duration of one second for a gas flow of 1000 sccm. Silicon pulse 32b and oxidizer pulse 36b, however, may have any suitable duration in order to yield a specific proportion of silicon relative to oxygen.

Referring back to FIG. 2, dielectric layer 14 may be formed such that nitrogen may be substantially uniformly introduced into dielectric layer 14. According to one embodiment, the composition of dielectric 14 may be controlled in order to yield a specific nitrogen profile and concentration. In some embodiments, non-stoichiometric portion 16a may result in a relatively high concentration of nitrogen.

FIG. 4 illustrates nitridation 18 of dielectric layer 14. According to one embodiment, a gate structure may be formed outwardly from dielectric layer 14. An electrical bias applied to the gate structure may induce a controlled electrical conduction path through a transistor channel of substrate 12. In this embodiment, nitrogen may be introduced into dielectric layer 14 to convert the layer into silicon oxynitride (SiON), which may provide a larger dielectric constant relative to silicon dioxide layers. According to one embodiment, nitrogen may be incorporated into non-stoichiometric portion 16a in a substantially uniform manner with little or no nitrogen reaching substrate 12.

Nitrogen may be introduced into dielectric layer 14 in any suitable manner such as by remote plasma nitridation, immersion plasma nitridation, or thermal nitridation. Plasma nitridation refers to exposing dielectric layer 14 to a nitrogen plasma. The nitrogen plasma includes a nitrogen source such as N₂ and one or more inert gases such as helium, argon, or xenon. Remote plasma nitridation may be performed by forming the plasma in an area away from semiconductor structure 10. Immersion plasma nitridation may be performed by forming the plasma in the same chamber that houses semiconductor structure 10.

Thermal nitridation may be performed by introducing nitrogen during growth at high temperatures. The nitrogen may be introduced using a primary nitrogen source and a diluent. The primary nitrogen source may comprise, for example, ammonia (NH₃) , nitric oxide (NO), or nitrous oxide (N₂O). The diluent may comprise, for example, nitrogen (N₂), helium (He), or argon (Ar). Based on various criteria, one skilled in the art may select an appropriate range for each of time, temperature, and pressure. For example, 60 minutes at greater than 500 degrees Celsius such as 1000 degrees Celsius in one atmosphere of NH₃. The high temperatures may be achieved by any suitable process, such as by using either a rapid thermal process or a furnace.

Alterations or permutations such as modifications, additions, or omissions may be made to semiconductor structure 10 without departing from the scope of the invention. Semiconductor structure 10 may have more, fewer, or other features.

FIG. 5 is a flowchart illustrating one embodiment of a method of fabricating semiconductor structure 10. Semiconductor structure 10 may be formed for various purposes, for example, for use in connection with a transistor. The method begins at step 100, where substrate 12 is provided. Substrate 12 may provide, for example, a transistor channel for a transistor, and may comprise silicon or any other suitable semiconductive material.

Dielectric layer 14 is deposited outwardly from substrate 12 at step 104. Dielectric layer 14 may provide, for example, a transistor gate insulator for a transistor. Dielectric layer 14 may be deposited in a controlled manner in order to achieve a specific non-stoichiometry, which may affect the nitridation of dielectric layer 14. Dielectric layer may be deposited by chemical vapor deposition, atomic layer deposition, or other suitable process.

Nitridation is performed at step 108. Nitrogen may be introduced into dielectric layer 14 to convert the layer to silicon oxynitride (SiON). Oxynitride material may provide a larger dielectric constant relative to silicon dioxide material. According to one embodiment, nitrogen may be incorporated into dielectric layer 14 in a substantially uniform manner with little or no nitrogen reaching substrate 12.

Structure 10 is annealed at step 112. Annealing may be performed in either an inert or oxidizing environment, where an inert ambient may comprise, for example, He, Ar, or N and an oxidizing ambient may comprise any suitable mixture including oxygen. The anneal may be performed under any suitable conditions. For example, the temperature may be in a range of 600 to 1100 degrees Celsius, the pressure may be in a range of one milliTorr to one atmosphere, and time may be in a range of one second to ten minutes. According to one embodiment, dielectric layer 14 may be annealed at a temperature greater than 650 degrees Celsius in a non-oxidizing ambient, and then annealed at a temperature less than 950 degrees Celsius in an oxidizing ambient.

Post-processing is performed at step 114. Post-processing steps may be ascertained by one skilled in the art according to various criteria relating to structure 10 as well as the implementation of structure 10. For example, if structure 10 is to be used as a transistor gate insulator, then other known transistor fabrication steps may be taken. For example, a gate conductive layer may be formed over the oxynitride and etched to form a gate stack. Either before or after the formation of the gate stack, implants may be formed in substrate 10 such as to form the transistor source and drain, and still others related regions and connections may be formed. After performing post-processing, the method terminates.

Alterations or permutations such as modifications, additions, or omissions may be made to the method without departing from the scope of the invention. The method may include more, fewer, or other steps. For example, annealing structure 10 at step 112 may be omitted. Additionally, steps may be performed in any suitable order without departing from the scope of the invention.

Certain embodiments of the invention may provide one or more technical advantages. A technical advantage of one embodiment may include forming a dielectric layer by depositing silicon oxide outwardly from a substrate, which may allow for formation at relatively low temperatures. Another technical advantage of one embodiment may be that the relative concentration of silicon and oxygen of the dielectric layer may be controlled to provide for specific nitridation. This may allow for a desired nitrogen profile for the dielectric layer.

Although an embodiment of the invention and its advantages are described in detail, a person skilled in the art could make various alterations, additions, and omissions without departing from the spirit and scope of the present invention as defined by the appended claims.

1. A method of fabricating a semiconductor structure, comprising:
establishing a non-stoichiometry associated with a dielectric layer, the non-stoichiometry associated with a degree, the degree of the non-stoichiometry corresponding to a nitrogen profile associated with the dielectric layer;
controlling deposition of the dielectric layer outwardly from a substrate to substantially yield the established non-stoichiometry of the dielectric layer; and
incorporating nitrogen into the dielectric layer to substantially yield the nitrogen profile corresponding to the established non-stoichiometry.

2. The method of claim 1, wherein controlling deposition of the dielectric layer outwardly from the substrate further comprises:
determining a proportion of silicon relative to oxygen of the dielectric layer, the proportion corresponding to the established non-stoichiometry; and
depositing the dielectric having the determined proportion of silicon relative to oxygen.

3. The method of claim 1, wherein controlling deposition of the dielectric layer outwardly from the substrate further comprises:
determining a proportion of silicon relative to oxygen of the dielectric layer, the proportion corresponding to the established non-stoichiometry; and
exposing the substrate to a gas flow comprising a precursor and an oxidizer to deposit the dielectric layer having the determined proportion of silicon relative to oxygen.

4. The method of claim 1, wherein controlling deposition of the dielectric layer outwardly from the substrate further comprises repeating the following until the dielectric layer having a predetermined proportion of silicon relative to oxygen is formed:
depositing silicon outwardly from the substrate; and
oxidizing the silicon.

5. The method of claim 1, wherein controlling deposition of the dielectric layer outwardly from the substrate further comprises repeating the following until the dielectric layer having a predetermined proportion of silicon relative to oxygen is formed:
depositing silicon outwardly from the substrate during a first pulse having a first duration; and
oxidizing the silicon during a second pulse having a second duration, the first duration and the second duration corresponding to the predetermined proportion.

6. The method of claim 1, wherein controlling deposition of the dielectric layer outwardly from the substrate further comprises repeating the following until the dielectric layer having a predetermined proportion of silicon relative to oxygen is formed:
depositing silicon outwardly from the substrate during a first number of pulses; and
oxidizing the silicon during a second number of pulses, the first number of pulses and the second number of pulses corresponding to the predetermined proportion.

7. The method of claim 1, wherein controlling deposition of the dielectric layer outwardly from the substrate further comprises repeating the following until the dielectric layer having a thickness and a predetermined proportion of silicon relative to oxygen is formed:
depositing silicon outwardly from the substrate using a first gas flow, the first gas flow associated with a silicon concentration, a first gas flow rate, and a first gas pressure; and
oxidizing the silicon using a second gas flow, the second gas flow associated with an oxidizer concentration, a second gas flow rate, and a second gas pressure; the silicon concentration, the first gas flow rate, the first gas pressure, the oxidizer concentration, the second gas flow rate, and the second gas pressure corresponding to the predetermined proportion.

8. The method of claim 1, wherein establishing the non-stoichiometry associated with the dielectric layer further comprises calculating a proportion of silicon relative to oxygen of the dielectric layer corresponding to the established non-stoichiometry.

9. The method of claim 1, wherein the dielectric layer has a thickness in the range of one monolayer to fifty Angstroms.

10. The method of claim 1, wherein the dielectric layer has a thickness in the range of one monolayer to twenty Angstroms.

11. A method of fabricating a semiconductor structure, comprising:
establishing a nitrogen profile associated with a dielectric layer;
controlling deposition of the dielectric layer outwardly from a substrate to substantially yield a non-stoichiometry of the dielectric layer, the non-stoichiometry associated with a degree, the degree of the non-stoichiometry corresponding to the established nitrogen profile; and
incorporating nitrogen into the dielectric layer to substantially yield the established nitrogen profile.

12. The method of claim 11, wherein controlling deposition of the dielectric layer outwardly from the substrate further comprises:
determining a proportion of silicon relative to oxygen of the dielectric layer, the proportion corresponding to the non-stoichiometry; and
depositing the dielectric having the determined proportion of silicon relative to oxygen.

13. The method of claim 11, wherein controlling deposition of the dielectric layer outwardly from the substrate further comprises:
determining a proportion of silicon relative to oxygen of the dielectric layer, the proportion corresponding to the non-stoichiometry; and
exposing the substrate to a gas flow comprising a silicon precursor and an oxidizer to deposit the dielectric layer having the determined proportion of silicon relative to oxygen.

14. The method of claim 11, wherein controlling deposition of the dielectric layer outwardly from the substrate further comprises repeating the following until the dielectric layer having a predetermined proportion of silicon relative to oxygen is formed:
depositing silicon outwardly from the substrate; and
oxidizing the silicon.

15. The method of claim 11, wherein controlling deposition of the dielectric layer outwardly from the substrate further comprises repeating the following until the dielectric layer having a predetermined proportion of silicon relative to oxygen is formed:
depositing silicon outwardly from the substrate during a first pulse having a first duration; and
oxidizing the silicon during a second pulse having a second duration, the first duration and the second duration corresponding to the predetermined proportion.

16. The method of claim 11, wherein controlling deposition of the dielectric layer outwardly from the substrate further comprises repeating the following until the dielectric layer having a thickness and a predetermined proportion of silicon relative to oxygen is formed:
depositing silicon outwardly from the substrate during a first number of pulses; and
oxidizing the silicon during a second number of pulses, the first number of pulses and the second number of pulses corresponding to the predetermined proportion.

17. The method of claim 11, wherein controlling deposition of the dielectric layer outwardly from the substrate further comprises repeating the following until the dielectric layer having a predetermined proportion of silicon relative to oxygen is formed:
depositing silicon outwardly from the substrate using a first gas flow, the first gas flow associated with a silicon concentration, a first gas flow rate, and a first gas pressure; and
oxidizing the silicon using a second gas flow, the second gas flow associated with an oxidizer concentration, a second gas flow rate, and a second gas pressure; the silicon concentration, the first gas flow rate, the first gas pressure, the oxidizer concentration, the second gas flow rate, and the second gas pressure corresponding to the predetermined proportion.

18. The method of claim 11, further comprising calculating a proportion of silicon relative to oxygen of the dielectric layer corresponding to established nitrogen profile.

19. A system of fabricating a semiconductor structure, comprising:
means for establishing a non-stoichiometry associated with a dielectric layer, the non-stoichiometry associated with a degree, the degree of the non-stoichiometry corresponding to a nitrogen profile associated with the dielectric layer;
means for controlling deposition of the dielectric layer outwardly from a substrate to substantially yield the established non-stoichiometry of the dielectric layer; and
means for incorporating nitrogen into the dielectric layer to substantially yield the nitrogen profile corresponding to the established degree of non-stoichiometry.

20. A method of fabricating a semiconductor structure, comprising:
establishing a non-stoichiometry associated with a dielectric layer by calculating a proportion of silicon relative to oxygen of the dielectric layer corresponding to the established non-stoichiometry, the non-stoichiometry associated with a degree, the degree of the non-stoichiometry corresponding to a nitrogen profile associated with the dielectric layer;
controlling deposition of the dielectric layer outwardly from a substrate to substantially yield the established non-stoichiometry of the dielectric layer, the dielectric layer having a thickness in the range of one monolayer to thirty Angstroms, the deposition of the dielectric layer controlled by depositing the dielectric having the determined proportion of silicon relative to oxygen by at least one of the following processes:
exposing the substrate to a gas flow comprising a silicon precursor and an oxidizer according to a first process to deposit the dielectric layer having the determined proportion of silicon relative to oxygen; and
repeating at least one of the following according to a second process until the dielectric layer having the proportion of silicon relative to oxygen is formed:
depositing silicon outwardly from the substrate during a first pulse having a first duration, and oxidizing the silicon during a second pulse having a second duration, the first duration and the second duration corresponding to the predetermined proportion;
depositing silicon outwardly from the substrate during a first number of pulses, and oxidizing the silicon during a second number of pulses, the first number of pulses and the second number of pulses corresponding to the predetermined proportion; and
depositing silicon outwardly from the substrate using a first gas flow, the first gas flow associated with a silicon concentration, a first gas flow rate, and a first gas pressure, and oxidizing the silicon using a second gas flow, the second gas flow associated with an oxidizer concentration, a second gas flow rate, and a second gas pressure; the silicon concentration, the first gas flow rate, the first gas pressure, the oxidizer concentration, the second gas flow rate, and the second gas pressure corresponding to the predetermined proportion; and
incorporating nitrogen into the dielectric layer to substantially yield the nitrogen profile corresponding to the established degree of non-stoichiometry.
